(19) United States
(12) Patent Application Publication
(10) Pub. No.: US 2024/0372039 A1
(43) Pub. Date: Nov. 7, 2024

(54) CONTACT INTERCONNECT STRUCTURES FOR LIGHT-EMITTING DIODE CHIPS AND RELATED METHODS

(71) Applicant: CreeLED, Inc., Durham, NC (US)

(72) Inventors: Steven Wuester, Wake Forest, NC (US); Michael Check, Holly Springs, NC (US)

(21) Appl. No.: 18/312,733

(22) Filed: May 5, 2023

(51) Int. Cl. H01L 33/40; H01L 33/38

(52) U.S. Cl. CPC H01L 33/405; H01L 33/382; H01L 2933/0016

(57) ABSTRACT

Solid-state lighting devices including light-emitting diodes (LEDs) and more particularly contact interconnect structures for LED chips and related methods are disclosed. Contact interconnect structures include arrangements of contact plugs and various interconnect segments that provide electrical connections to certain layers of active LED structures. Exemplary interconnect structures include contact plugs at interfaces of the active LED structure for facilitating ohmic contact behavior, followed by multiple interconnect segments that extend through one or more insulating layers of LED chips. By providing multiple interconnect segments, materials used for the overall interconnect structure may be positionally varied. Interconnect segments proximate the contact plug may have a same material as metal reflective layers used in other parts of the LED chip for increased reflectivity and improved reliability. Interconnect segments may also be formed with lateral extensions that are embedded within the LED chip for further increased reflectivity.

### FIELD OF THE INVENTION

The present disclosure relates to solid-state lighting devices including light-emitting diodes (LEDs) and more particularly to contact interconnect structures for LED chips and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. If photons are internally reflected in a repeated manner, then such photons will eventually be absorbed and never provide visible light that exits an LED. The quantum efficiency of an LED can also be limited by other factors, such as how well current is able to spread within an LED. To increase current spreading for LEDs, and in particular for larger area LEDs, it has been found useful to add layers of high electrical conductivity over one or more epitaxial layers of an LED. Additionally, electrodes for the LEDs can have larger surface areas and may include various electrode extensions configured to route and more evenly distribute current across an LED.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs) and more particularly to contact interconnect structures for LED chips and related methods. Contact interconnect structures include arrangements of contact plugs and various interconnect segments that provide electrical connections to certain layers of active LED structures. Exemplary interconnect structures include contact plugs at interfaces of the active LED structure for facilitating ohmic contact behavior, followed by multiple interconnect segments that extend through one or more insulating layers of LED chips. By providing multiple interconnect segments, materials used for the overall interconnect structure may be positionally varied. Interconnect segments proximate the contact plug may have a same material as metal reflective layers used in other parts of the LED chip for increased reflectivity and improved reliability. Interconnect segments may also be formed with lateral extensions that are embedded within the LED chip for further increased reflectivity.

In one aspect, an LED chip comprises: an active LED structure comprising an n-type layer, a p-type layer, and an active layer that is between the n-type layer and the p-type layer; and an n-contact interconnect arranged to extend through the p-type layer and the active layer to contact a portion of the n-type layer, the n-contact interconnect comprising a contact plug and a first n-contact interconnect segment, the contact plug being arranged between the first n-contact interconnect segment and the n-type layer. In certain embodiments, the contact plug forms a plurality of discontinuous regions on the n-type layer, and the first n-contact interconnect segment contacts the n-type layer between adjacent regions of the plurality of discontinuous regions. In certain embodiments, the contact plug comprises chromium, aluminum-doped zinc oxide, or indium tin oxide. In certain embodiments, the contact plug has a thickness in a range from 10 angstroms to less than 40 angstroms.

The LED chip may further comprise: a dielectric reflector layer on the p-type layer; a metal reflector layer on the dielectric reflector layer; and a plurality of reflective layer interconnects that extend from the metal reflector layer and through the dielectric reflector layer to form an electrically conductive path to the p-type layer. In certain embodiments, the metal reflector layer and the first n-contact interconnect segment comprise a same material. In certain embodiments, the same material comprises silver. In certain embodiments, the first n-contact interconnect segment forms an extension that laterally extends on the dielectric reflector layer. The LED chip may further comprise a passivation layer on the metal reflector layer, wherein the extension is between the dielectric reflector layer and the passivation layer. The LED chip may further comprise a second n-contact interconnect segment that extends through the passivation layer and is electrically coupled to the first n-contact interconnect segment. In certain embodiments, a width of the second n-contact interconnect segment is less than a width of the extension of the first n-contact interconnect segment. In certain embodiments, a width of the second n-contact interconnect segment is greater than a width of the extension of the first n-contact interconnect segment. The LED chip may further comprise a first barrier layer on the extension of the first n-contact interconnect segment and a second barrier layer between the second n-contact interconnect segment and the first barrier layer, wherein a width of the second barrier layer is greater than a width of the first barrier layer.

The LED chip may further comprise a p-contact electrically coupled to the p-type layer and an n-contact electrically coupled to the n-contact interconnect, wherein the p-contact and the n-contact are arranged on a same side of the active LED structure.

The LED chip may further comprise a carrier submount on which the active LED structure is provided and a contact electrically coupled to the active LED structure, wherein the contact is positioned laterally adjacent the active LED structure.

In another aspect, an LED chip comprises an n-type layer, a p-type layer, and an active layer that is between the n-type layer and the p-type layer; a dielectric reflector layer on the active LED structure; and a first n-contact interconnect segment that extends through the dielectric reflector layer, the p-type layer, and the active layer to contact a portion of the n-type layer, the first n-contact interconnect segment forming an extension that laterally extends on a surface of the dielectric reflector layer. The LED chip may further comprise a passivation layer on the dielectric reflector layer, wherein the extension of the first n-contact interconnect segment is between the passivation layer and the dielectric reflector layer. The LED chip may further comprise a second n-contact interconnect segment that extends through the passivation layer and is electrically coupled to the first n-contact interconnect segment. In certain embodiments, a width of the second n-contact interconnect segment is less than a width of the extension of the first n-contact interconnect segment. The LED chip may further comprise a first barrier layer on the extension of the first n-contact interconnect segment and a second barrier layer between the second n-contact interconnect segment and the first barrier layer, wherein a width of the second barrier layer is greater than a width of the first barrier layer. The LED chip may further comprise a contact plug between the first n-contact interconnect segment and the n-type layer. In certain embodiments, the contact plug forms a plurality of discontinuous regions on the n-type layer, and the first n-contact interconnect segment contacts the n-type layer between adjacent regions of the plurality of discontinuous regions.

In another aspect, a method comprises: providing an active light-emitting diode (LED) structure comprising an active layer between an n-type layer and a p-type layer, and a first opening that extends through the p-type layer, the active layer, and a portion of the n-type layer; depositing a dielectric layer on the p-type layer and within the first opening; forming a second opening within the first opening, the second opening extending through the dielectric layer to the n-type layer; and depositing a first n-contact interconnect segment within the second opening, the first n-contact interconnect segment forming a lateral extension along a surface of the dielectric layer adjacent to the second opening. The method may further comprise depositing a contact plug on the n-type layer within the second opening before depositing the first n-contact interconnect segment. The method may further comprise depositing a metal layer such that a first portion of the metal layer forms a reflective layer on the dielectric layer and a second portion of the metal layer forms the first n-contact interconnect segment. The method may further comprise depositing a first portion of a barrier layer on the reflective layer and a second portion of the barrier layer on the first n-contact interconnect segment. In certain embodiments, an extension of the first n-contact interconnect segment laterally extends on a surface of the dielectric layer adjacent to the second opening. The method may further comprise depositing a passivation layer on the extension of the first n-contact interconnect segment.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of an exemplary light-emitting diode (LED) chip arranged in a flip-chip configuration according to principles of the present disclosure.

FIG. 1B is an expanded view of an interface between an n-type layer and a contact plug of the LED chip of FIG. 1A for embodiments where the contact plug forms a plurality of discontinuous regions on the n-type layer.

FIG. 2 is a cross-sectional view of an LED chip that is similar to the LED chip of FIG. 1A for embodiments where a second n-contact interconnect segment has a greater width than an extension of a first n-contact interconnect segment and a barrier layer that is on the extension.

FIG. 3A is a cross-sectional view of the LED chip of FIG. 1A at a fabrication step where various openings are formed for the first n-contact interconnect segment and contact plug.

FIG. 3B is a cross-sectional view of the LED chip of FIG. 3A at a subsequent fabrication step after the contact plug is formed on the n-type layer within a second opening.

FIG. 3C is a cross-sectional view of the LED chip of FIG. 3B at a subsequent fabrication step after a second reflective layer, the first n-contact interconnect segment, and the barrier layer are formed.

FIG. 3D is a cross-sectional view of the LED chip of FIG. 3C at a subsequent fabrication step after a passivation layer is formed and fourth and fifth openings are formed in the passivation layer.

FIG. 3E is a cross-sectional view of the LED chip of FIG. 3D at a subsequent fabrication step after a p-contact and an n-contact are formed on the passivation layer.

FIG. 4 is a cross-sectional view of another LED chip according to principles of the present disclosure for generally vertical chip structures.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to contact interconnect structures for LED chips and related methods. Contact interconnect structures include arrangements of contact plugs and various interconnect segments that provide electrical connections to certain layers of active LED structures. Exemplary interconnect structures include contact plugs at interfaces of the active LED structure for facilitating ohmic contact behavior, followed by multiple interconnect segments that extend through one or more insulating layers of LED chips. By providing multiple interconnect segments, materials used for the overall interconnect structure may be positionally varied. Interconnect segments proximate the contact plug may have a same material as metal reflective layers used in other parts of the LED chip for increased reflectivity and improved reliability. Interconnect segments may also be formed with lateral extensions that are embedded within the LED chip for further increased reflectivity.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material

systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), GaN, with a suitable substrate being a 4H polytype of SiC, although other SiC polytypes can also be used including 3C, 6H, and 15R polytypes. SiC has certain advantages, such as a closer crystal lattice match to Group Ill nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light transmissive optical properties.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations. In certain embodiments, one or more surfaces of LED chips may be conformally coated with one or more lumiphoric materials, while other surfaces of such LED chips and/or associated submounts may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) are coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described may also be applicable to flip-chip structures where anode and cathode connections are made from a same side of the LED chip for flip-chip mounting to another surface.

The present disclosure may be useful for LED chips with current spreading structures that distribute current across active LED structure areas. Current spreading structures may include various contacts, interconnects, and electrically conductive layers that effectively route current across an LED chip for reduced current crowding. N-contact interconnect structures may include electrically conductive materials that contact an n-type layer of the active LED structure. Various LED chips, including large area LED chips, typically include a plurality of n-contact interconnects that are distributed across an area of the active LED structure. The n-contact interconnects provide multiple electrical connection points to the n-type layer, and the n-contact interconnects may be connected to one or more n-contacts of the LED chip. Common materials for n-contact interconnects include materials with high electrical conductivity, such as Al, tin (Sn), and gold (Au), among others. However, such materials may be subject to reliability issues during operation due to various factors, such as metal migration. For example, Al migration can cause interconnects to shrink and become visibly darker, thereby increasing absorption of light within the LED chip. Additionally, migration and temperature cycling associated with operation can leave interconnects more brittle and prone to cracking.

According to aspects of the present disclosure, improved n-contact interconnect structures are provided. N-contact interconnects may include contact plugs at surfaces of n-type layers for ensuring good ohmic contact, followed by various improved structures, such as multiple n-contact interconnect segments that extend through multiple passivation layers, thereby allowing different materials to be used for different portions of n-contact interconnects. In this manner, certain materials may be implemented that are less prone to cracking and/or darkening during use. In certain embodiments, a first n-contact interconnect segment may be formed on the contact plug at the n-type layer, and a second n-contact interconnect segment may electrically couple a first n-contact material to an n-contact of the LED chip. Exemplary contact plug materials include chromium (Cr) or alloys thereof, Al-doped zinc (Zr) oxide, and indium tin oxide (ITO), which provide work function matching for good ohmic contact behavior with the n-type layer. Exemplary materials for the first n-contact interconnect segment may include Ag for increased reflectivity. The first n-contact interconnect segments may further include lateral extensions between passivation layers for further increased reflectivity.

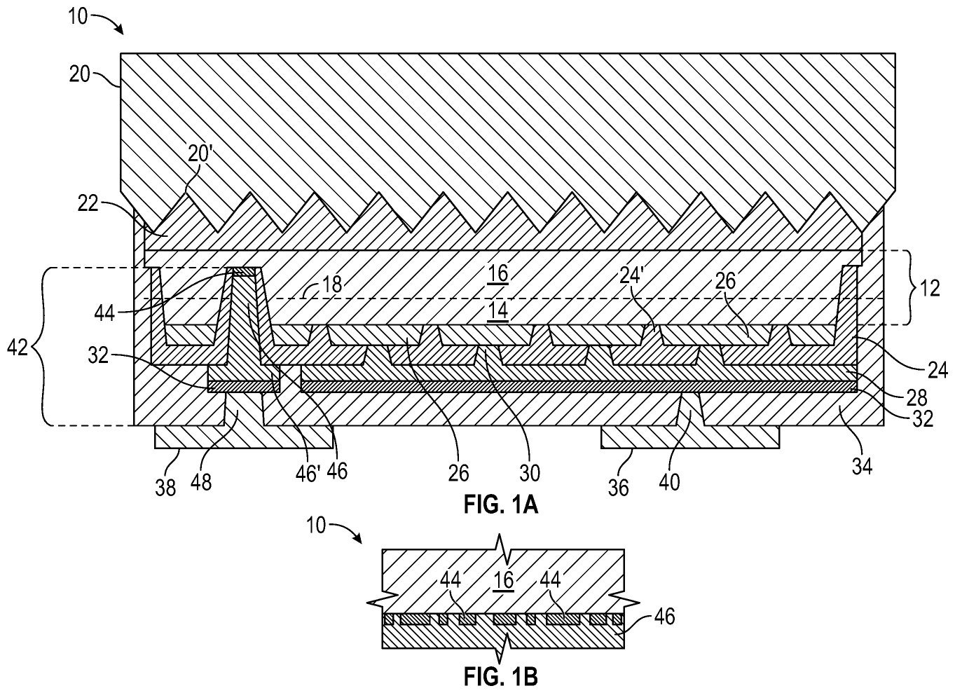

FIG. 1A is a cross-sectional view of an exemplary LED chip 10 arranged in a flip-chip configuration according to principles of the present disclosure. The LED chip 10 includes an active LED structure 12 comprising a p-type layer 14, an n-type layer 16, and an active layer 18 formed on a substrate 20. In certain embodiments, one or more buffer layers and/or undoped layers 22 may be provided between the substrate 20 and the active LED structure 12. The substrate 20 may embody a patterned substrate such that a surface 20′ of the substrate 20 closest to the active LED structure 12 is patterned. In certain embodiments, the n-type layer 16 is between the active layer 18 and the substrate 20. In other embodiments, the doping order may be reversed. The substrate 20 can comprise many different materials such as SiC or sapphire and can have one or more surfaces that are shaped, textured, or patterned to enhance light extraction. In certain embodiments, the substrate 20 is light transmissive (preferably transparent) and may include a patterned surface 20′ that is proximate the active LED structure 12 and includes multiple recessed and/or raised features.

In FIG. 1A, a first reflective layer 24 is provided on portions of the p-type layer 14 with a current spreading layer 26 therebetween. The first reflective layer 24 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the first reflective layer 24 comprises a material with an index of refraction lower than the index of refraction of the active LED structure 12 material. The first reflective layer 24 may comprise many different materials, with some having an index of refraction less than 2.3, while others can have an index of refraction less than 2.15, less than 2.0, and less than 1.5. In some embodiments, the first reflective layer 24 comprises a dielectric material, with some embodiments comprising silicon dioxide (SiO₂) and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. Accordingly, the first reflective layer 24 may be referred to as a dielectric reflector layer and/or a dielectric reflective layer. In certain embodiments, the first reflective layer 24 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with the active LED structure 12 comprising GaN and the first reflective layer 24 comprising SiO₂ can have a sufficient index of refraction step between the two to allow for efficient TIR of light. The first reflective layer 24 can have different thicknesses depending on the type of materials used, with some embodiments having a thickness of at least 0.2 microns (μm). In some of these embodiments, the first reflective layer 24 can have a thickness in the range of 0.2 μm to 0.7 μm, while in some of these embodiments the thickness can be approximately 0.5 μm. Portions of the first reflective layer 24 may extend along mesa sidewalls of the active LED structure 12 and along sidewall portions of the p-type layer 14, the active layer 18, and the n-type layer 16.

The current spreading layer 26 may embody a layer of conductive material, for example a transparent conductive oxide such as indium tin oxide (ITO) or a metal such as platinum (Pt), although other materials may be used. In certain embodiments, the current spreading layer 26 is formed with a number of openings or even discontinuous regions on the p-type layer 14. This arrangement allows portions 24′ of the first reflective layer 24 to extend through the current spreading layer 26 and contact the p-type layer 14. In this manner, interfaces formed between the p-type layer 14 and the first reflective layer 24 that do not include the current spreading layer 26 may exhibit increased reflectivity to light generated by the active LED structure 12. Even though the current spreading layer 26 does not continuously cover the p-type layer 14, the openings or discontinuous regions of the current spreading layer 26 may have small enough lateral dimensions to still suitably spread current along the p-type layer 14. In other arrangements, the current spreading layer 26 could continuously cover the p-type layer 14.

The LED chip 10 may further include a second reflective layer 28 that is on the first reflective layer 24 such that the first reflective layer 24 is arranged between the active LED structure 12 and the second reflective layer 28. The second reflective layer 28 may include a metal layer that is configured to reflect any light from the active LED structure 12 that may pass through the first reflective layer 24. The second reflective layer 28 can comprise many different materials such as Ag, gold (Au), or combinations thereof. Accordingly, the second reflective layer 28 may be referred to as a metal reflector layer and/or a metal reflective layer. As illustrated, the second reflective layer 28 may include one or more reflective layer interconnects 30 that provide electrically conductive paths through the first reflective layer 24 to the current spreading layer 26. In certain embodiments, the reflective layer interconnects 30 comprise reflective layer vias. Accordingly, the first reflective layer 24, the second reflective layer 28, and the reflective layer interconnects 30 form a reflective structure of the LED chip 10. In some embodiments, the reflective layer interconnects 30 comprise the same material as the second reflective layer 28 and are formed at the same time as the second reflective layer 28. In other embodiments, the reflective layer interconnects 30 may comprise a different material than the second reflective layer 28. The LED chip 10 may also comprise a barrier layer 32 on a side of the second reflective layer 28 opposite the first reflective layer 24 to prevent migration of the second reflective layer 28 material, such as Ag, to other layers. Preventing this migration helps the LED chip 10 maintain efficient operation through its lifetime. The barrier layer 32 may comprise an electrically conductive material, with suitable materials including but not limited to sputtered Ti/Pt followed by evaporated Au bulk material or sputtered Ti/Ni followed by an evaporated Ti/Au bulk material. A passivation layer 34 is included on the barrier layer 32 as well as any portions of the second reflective layer 28 that may be uncovered by the barrier layer 32. The passivation layer 34 may further be arranged on portions of the first reflective layer 24 that are uncovered by the second reflective layer 28. The passivation layer 34 protects and provides electrical insulation for the LED chip 10 and can comprise many different materials, such as a dielectric material. In certain embodiments, the passivation layer 34 is a single layer, and in other embodiments, the passivation layer 34 comprises a plurality of layers. A suitable material for the passivation layer 34 includes but is not limited to SiN, SiNx, and/or Si₃N₄. In certain embodiments, the first reflective layer 24 comprises SiO₂ and the passivation layer 34 comprises SiN, SiNx, or Si₃N₄. In other embodiments, the first reflective layer 24 and at least a portion of the passivation layer 34 may each comprise SiO₂. As illustrated, the first reflective layer 24 may bound perimeter and/or sidewall portions of the active LED structure 12, including the p-type layer 14, the active layer 18, and the n-type layer 16 along a perimeter of the LED chip 10. Furthermore, the passivation layer 34 may be arranged to also bound perimeter portions of the active LED structure 12 where the passivation layer 34 extends to the substrate 20. In this manner, portions of the first reflective layer 24 may be arranged between portions of the passivation layer 34 along sidewalls of active LED structure 12 for enhanced passivation and protection.

In FIG. 1A, the LED chip 10 comprises a p-contact 36 and an n-contact 38 that are arranged on the passivation layer 34 and are configured to provide electrical connections with the active LED structure 12. The p-contact 36, which may also be referred to as an anode contact, may comprise one or more p-contact interconnects 40 that extend through the passivation layer 34 to the barrier layer 32 or the second reflective layer 28 to provide an electrical path to the p-type layer 14. In certain embodiments, the one or more p-contact interconnects 40 comprise one or more p-contact vias. The n-contact 38, which may also be referred to as a cathode contact, is electrically coupled to the n-type layer 16 by way of one or more n-contact interconnects 42 that extend through the passivation layer 34, the barrier layer 32, the first and second reflective layers 24, 28, the p-type layer 14, and the active layer 18. In certain embodiments, the one or more n-contact interconnects 42 may be referred to as one or more n-contact vias. Openings for the n-contact interconnects 42 may be formed in a separate etching step than etching along the perimeter of the LED chip 10 where the passivation layer 34 bounds the active LED structure 12.

In operation, a signal applied across the p-contact 36 and the n-contact 38 is conducted to the p-type layer 14 and the n-type layer 16, causing the LED chip 10 to emit light from the active layer 18. The p-contact 36 and the n-contact 38 can comprise many different materials such as Au, copper (Cu), nickel (Ni), In, Al, Ag, tin (Sn), Pt, or combinations thereof. In still other embodiments, the p-contact 36 and the n-contact 38 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. As described above, the LED chip 10 is arranged for flip-chip mounting and the p-contact 36 and n-contact 38 are configured to be mounted or bonded to a surface, such as a printed circuit board. While FIG. 1A is described in the context of a flip-chip structure, the principles disclosed for one or more of the current spreading layer 26, the first reflective layer 24, the second reflective layer 28, and the barrier layer 32 are readily applicable to other chip structures.

For illustrative purposes, FIG. 1A is shown with a single n-contact interconnect 42. In practice, the LED chip 10 may include multiple n-contact interconnects 42 spaced apart in an array pattern across the active LED structure 12. As illustrated, the n-contact interconnect 42 is collectively formed of a structure of several elements. The n-contact interconnect 42 may include a contact plug 44 at an interface with the n-type layer 16. The contact plug 44 comprises a material, such as Cr or alloys thereof, Al-doped ZnO, or ITO, that provides sufficient work function matching to promote good ohmic contact behavior with the n-type layer 16. The contact plug 44 may be relatively thin to avoid light absorption, such as a thickness of less than 40 angstroms (Å), or in a range from 10 Å to 40 Å, or in a range from 10 Å to 35 Å. The n-contact interconnect 42 further includes a first n-contact interconnect segment 46 on the contact plug 44 such that the contact plug 44 is between the n-type layer 16 and the first n-contact interconnect segment 46. The first n-contact interconnect segment 46 may extend through a portion or opening of the first reflective layer 24, the current spreading layer 26, the p-type layer 14, the active layer 18, and a portion of the n-type layer 16. The first reflective layer 24 may cover sidewalls of the p-type layer 14, the active layer 18, and the n-type layer 16 within the opening to prevent electrical shorting. In certain embodiments, the first n-contact interconnect segment 46 may include Ag or alloys thereof to promote increased reflectivity within the opening. In certain embodiments, the first n-contact interconnect segment 46 may include a same material as the second reflective layer 28. Advantageously, the first n-contact interconnect segment 46 may therefore be formed in a same fabrication step as the second reflective layer 28 to reduce manufacturing costs.

In certain embodiments, the first n-contact interconnect segment 46 forms an extension 46′ that laterally extends between the first reflective layer 24 and the passivation layer 34. As such, the extension 46′ is effectively embedded within the LED chip 10 proximate the opening for the n-contact interconnect segment 46. In this manner, the extension 46′ thereby provides additional reflectivity to redirect light from the active LED structure 12 toward and through the substrate 20. A portion of the barrier layer 32 may further be arranged on the first n-contact interconnect segment 46 and extension 46′ thereof to reduce metal migration. To prevent electrical shorting, the extension 46′ and corresponding portion of the barrier layer 32 may be electrically isolated from the second reflective layer 28 and the remainder of the barrier layer 32 by a portion of the passivation layer 34.

The n-contact interconnect 42 may further include a second n-contact interconnect segment 48 that electrically couples the n-contact 38 to the first n-contact interconnect segment 46 and barrier layer 32, when present. The second n-contact interconnect segment 48 extends through the passivation layer 34 to contact the first n-contact interconnect segment 46 and/or barrier layer 32. In certain embodiments, the second n-contact interconnect segment 48 comprises a same material as the n-contact 38 and is formed in a same fabrication step. In certain embodiments, the first n-contact interconnect segment 46 and the second n-contact interconnect segment 48 comprise different materials. As illustrated, a width of the second n-contact interconnect segment 48 is less than a corresponding width of the barrier layer 32 and/or the extension 46′ of the first n-contact interconnect segment 46. In this manner, downward propagating light may be reflected or otherwise redirected by the first n-contact interconnect segment 46 and extension 46′ thereof before reaching the second n-contact interconnect segment 48.

FIG. 1B is an expanded view of an interface between the n-type layer 16 and the contact plug 44 of the LED chip 10 of FIG. 1A for embodiments where the contact plug 44 forms a plurality of discontinuous regions on the n-type layer 16. In certain embodiments, the contact plug 44 is formed to be as thin as possible while still providing sufficient ohmic contact behavior with the n-type layer 16. For example, the thickness of less than 40 Å, or in a range from 10 Å to 40 Å, or in a range from 10 Å to 35 Å described above may promote discontinuous regions of the contact plug 44. This allows the first n-contact interconnect segment 46 to contact, or even directly contact, the n-type layer 16 between adjacent ones of the discontinuous regions of the contact plug 44. Such a structure may be advantageous for embodiments where the material of the contact plug 44 is not as reflective as the material of the first n-contact interconnect segment 46. In the various embodiments described above and below, the contact plug 44 could have a structure with discontinuous regions as illustrated in FIG. 1B or a continuous layer as illustrated in FIG. 1A.

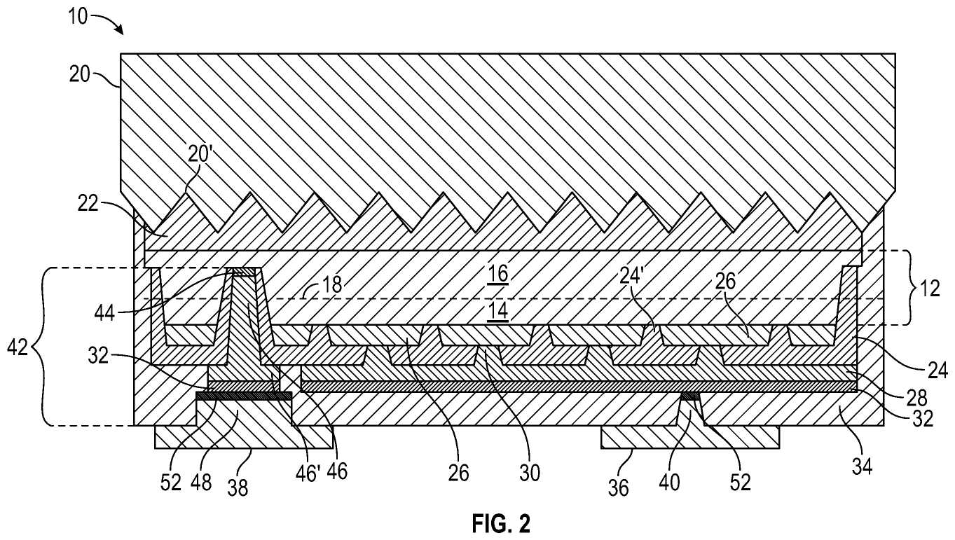

FIG. 2 is a cross-sectional view of an LED chip 50 that is similar to the LED chip 10 of FIG. 1A for embodiments where the second n-contact interconnect segment 48 has a greater width than the extension 46′ of the first n-contact interconnect segment 46 and the barrier layer 32 that is on the extension 46′. Greater widths may improve manufacturing tolerances for electrically connecting the first and second n-contact interconnect segments 46, 48. In certain embodiments, an additional or second barrier layer 52 may form an intermediate layer between the second n-contact interconnect segment 48 and the barrier layer 32 and/or first n-contact interconnect segment 46. In this manner, the additional barrier layer 52 may be formed after the passivation layer 34 to effectively form a barrier across the larger width of the second n-contact interconnect segment 48. The additional barrier layer 52 may comprise an electrically conductive metal material, including Ni and/or Ni intermetallics. In certain embodiments, the width of the second n-contact interconnect segment 48 could be the same as a corresponding width of the extension 46′ and/or barrier layer 32.

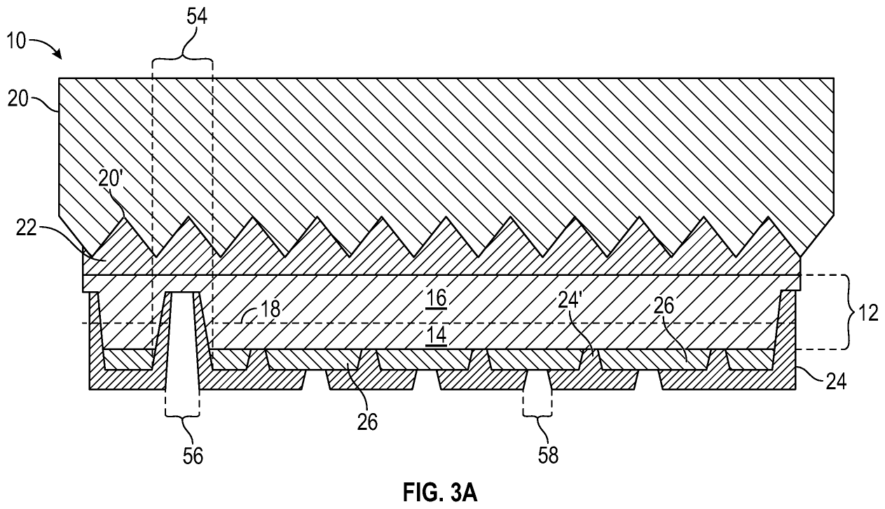

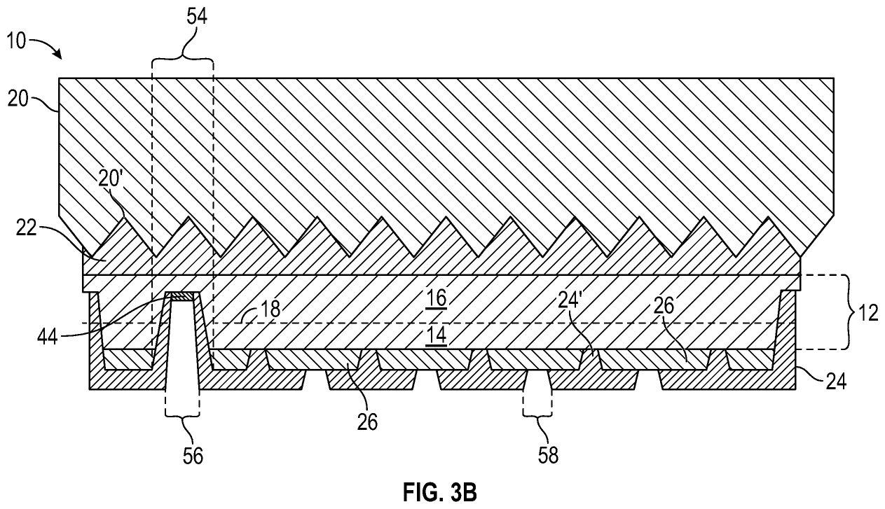

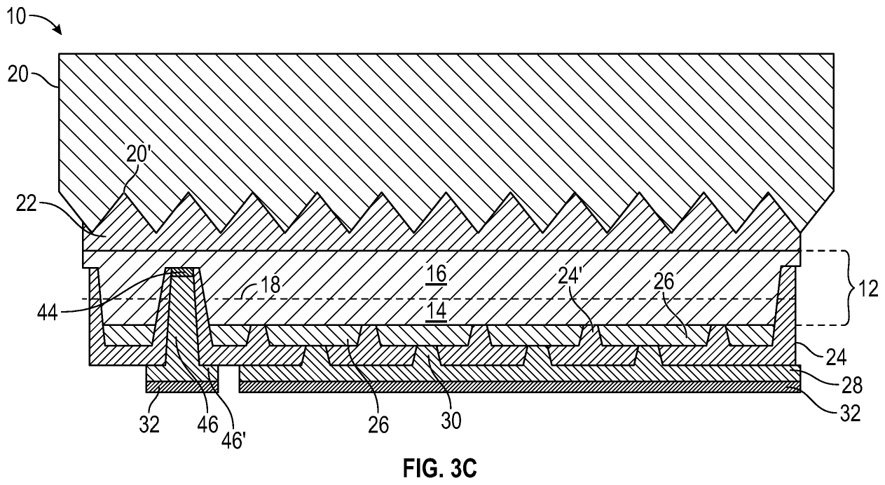

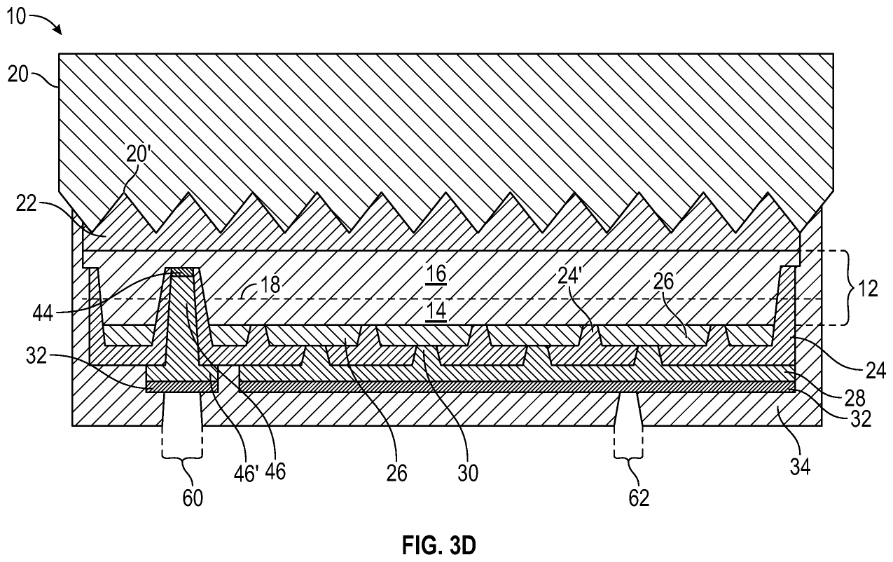

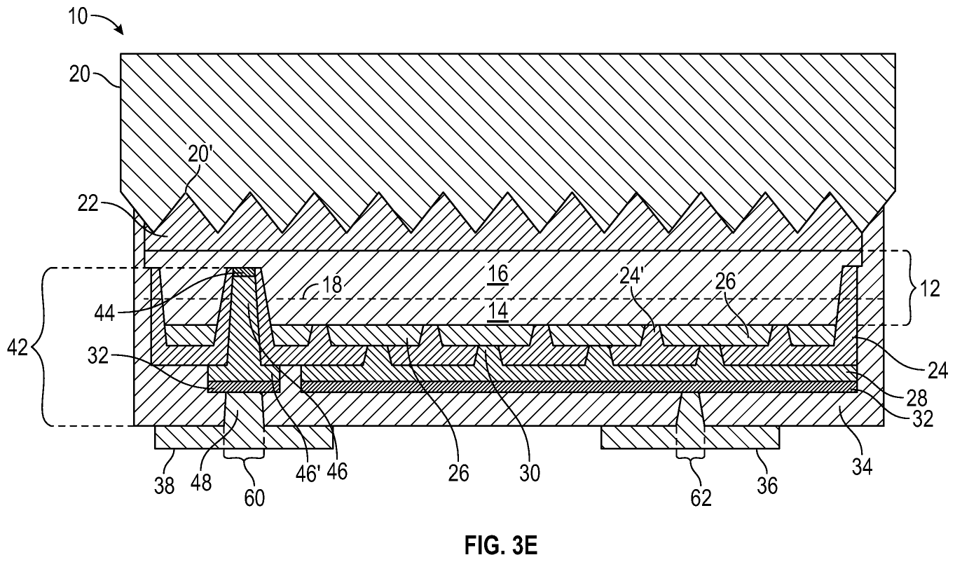

FIGS. 3A to 3E are cross-sectional views of the LED chip 10 of FIG. 1A and/or FIG. 1B at various fabrication steps. While the fabrication steps are illustrated in the context of the LED chip 10 of FIG. 1A, the principles described are also applicable to other LED chips, such as the LED chip 50 of FIG. 2. The orientation of the LED chip 10 in FIGS. 3A to 3E is shown in the final flip-chip orientation. However, during various fabrication steps, it is appreciated that the LED chip 10 may be oriented such that the substrate 20 is down and the p-type layer 14 is up to accommodate topside fabrication. After the completed structure of the LED chip 10 as illustrated in FIG. 3E is achieved, the LED chip 10 may then be oriented for flip-chip mounting as illustrated. Additionally, FIGS. 3A to 3E are shown in the context of a single n-contact interconnect 42 for illustrative purposes. However, it is appreciated that the fabrication sequence is equally applicable for the LED chip 10 including multiple n-contact interconnects 42 formed in a spaced apart manner across the LED chip 10.

FIG. 3A is a cross-sectional view of the LED chip 10 of FIG. 1A at a fabrication step where various openings are formed for the first n-contact interconnect segment 46 and contact plug 44 of FIG. 1A. As illustrated, a first opening 54 is formed through the current spreading layer 26 (when present), the p-type layer 14, the active layer 18, and into a portion of the n-type layer 16, thereby exposing a surface of the n-type layer 16 within the opening 54. The first reflective layer 24 has also been blanket deposited across the LED chip 10, within the first opening 54, and along sidewalls of the current spreading layer 26, the p-type layer 14, the active layer 18, and the n-type layer 16 within the first opening 54. Next, a second opening 56 is formed through the first reflective layer 24 and within the first opening 54 to provide access to the n-type layer 16. Additionally, one or more third openings 58 may be formed through the first reflective layer 24 to provide access to the p-type layer 14 and/or current spreading layer 26. In certain embodiments, the second and third openings 56 and 58 may be formed during a same fabrication step to save costs. In other embodiments, the second and third openings 56 and 58 may be formed during different fabrication steps. For embodiments where the later formed passivation layer 34 is configured to bound the perimeter of the LED chip 10 all the way to the substrate 20, perimeter streets may be formed that bound the active LED structure 12 and first reflective layer 24 while exposing perimeter portions of the substrate 20.

FIG. 3B is a cross-sectional view of the LED chip 10 of FIG. 3A at a subsequent fabrication step after the contact plug 44 is formed on the n-type layer 16 within the second opening 56. The contact plug 44 may be selectively deposited within the second opening 56 by way of masking. In certain embodiments, the contact plug 44 may form discontinuous regions as illustrated in FIG. 1B.

FIG. 3C is a cross-sectional view of the LED chip 10 of FIG. 3B at a subsequent fabrication step after the second reflective layer 28, the first n-contact interconnect segment 46, and the barrier layer 32 are formed. In certain embodiments, the second reflective layer 28 and the first n-contact interconnect segment 46 comprise a same material and are deposited concurrently during a same selective deposition step. Accordingly, the first n-contact interconnect segment 46 and the second reflective layer 28 may form discontinuous portions of the same metal layer. In this manner, the third openings 58 may be concurrently filled to form the reflective layer interconnects 30. In a similar manner, the second opening 56 may be concurrently filled to form the first n-contact interconnect segment 46. Additionally, the extensions 46′ of the first n-contact interconnect segment 46 may laterally extend on surfaces of the first reflective layer 24 that are adjacent the second opening 56. As described above, such an arrangement may provide increased reflectivity for light that may not be reflected by the first reflective layer.

FIG. 3D is a cross-sectional view of the LED chip 10 of FIG. 3C at a subsequent fabrication step after the passivation layer 34 is formed and fourth and fifth openings 60, 62 are formed in the passivation layer 34. The fourth opening 60 is formed to provide access to the first n-contact interconnect segment 46 and corresponding portion of the barrier layer 32. The fifth opening 62 is formed to provide access to the second reflective layer 28 and other corresponding portions of the barrier layer 32. As illustrated, portions of the passivation layer 34 may be formed along the streets that bound perimeters of the active LED structure 12 and the first reflective layer 24 such that the passivation layer 34 extends all the way to the substrate 20 along the perimeter of the LED chip 10.

FIG. 3E is a cross-sectional view of the LED chip 10 of FIG. 3D at a

subsequent fabrication step after the p-contact 36 and the n-contact 38 are formed on the passivation layer 34. The metal of the p-contact 36 may fill the fifth opening 62 to form the p-contact interconnect 40. In a similar manner, the metal of the n-contact 38 may fill the fourth opening 60 to form the second n-contact interconnect segment 48. In certain embodiments, the p-contact 36, the p-contact interconnect 40, the n-contact 38, and the second n-contact interconnect segment 48 may be formed concurrently.

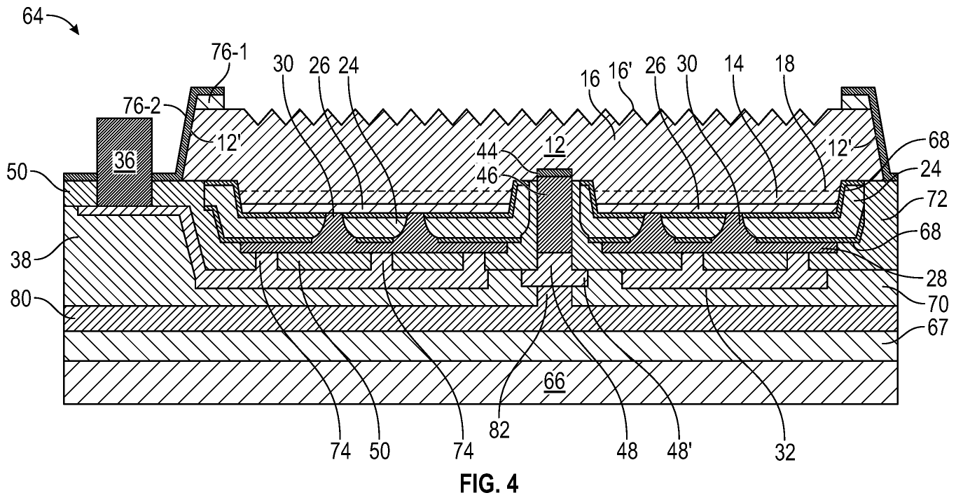

FIG. 4 is a cross-sectional view of another LED chip 64 according to principles of the present disclosure for generally vertical chip structures. The LED chip 64 includes many of the same layers with the same compositions described above for the LED chip 10. As such, common elements are provided with common numbering. In FIG. 4, the active LED structure 12 is formed on a carrier submount 66. In certain embodiments, the carrier submount 66 comprises an electrically conductive material such that the carrier submount 66 is part of electrically conductive connections to the active LED structure 12. The LED chip 64 may include the current spreading layer 26, the first reflective layer 24, the second reflective layer 28, and reflective layer interconnects 30 as described above. For the vertical chip structure, the p-contact 36 may be accessible from a top side of the LED chip 64 in a position that is laterally adjacent to the active LED structure 12. The n-contact 38 of FIG. 1A may be formed by the carrier submount 66 or as an additional layer on a bottom side of the carrier submount 66. The orientation of the LED chip 64 of FIG. 4 is intended to be mounted at the carrier submount 66.

The active LED structure 12 may initially be formed by epitaxially growing or depositing the n-type layer 16, the active layer 18, and the p-type layer 14 sequentially on a growth substrate, such as the substrate 20 of FIG. 1A. The active LED structure 12 may then be flipped and bonded to the carrier submount 66 by way of one or more bond metals 67 and the growth substrate is then removed. In this manner, a top surface 16′ of the n-type layer 16 forms a primary light extracting face of the LED chip 64. In certain embodiments, the top surface 16′ may comprise a textured or patterned surface for improving light extraction. In other embodiments, the doping order may be reversed such that the n-type layer 16 is arranged between the active layer 18 and the carrier submount 66.

Certain embodiments may also comprise one or more adhesion layers 68 positioned at one or more interfaces between the first reflective layer 24 and the second reflective layer 28 and/or interfaces between the first reflective layer 24 and the current spreading layer 26 to promote improved adhesion therebetween. Many different materials can be used for the adhesion layer 68, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlₓO_{y}. In certain embodiments, the adhesion layer comprises AlₓO_{y}, where 1≤x≤4 and 1≤y≤6. In certain embodiments, the adhesion layer comprises AlₓO_{y}, where x=2 and y=3, or Al₂O₃. The adhesion layer 68 may be deposited by electron beam deposition that may provide a smooth, dense, and continuous layer without notable variations in surface morphology. The adhesion layer 68 may also be deposited by sputtering, chemical vapor deposition, plasma enhanced chemical vapor deposition, or atomic layer deposition (ALD). In certain embodiments, the LED chip of FIG. 1A may also have one or more adhesion layers 68 as described for FIG. 4.

The LED chip 64 may further include a first passivation layer 70 on the barrier layer 32 as well as any portions of the second reflective layer 28 that may be uncovered by the barrier layer 32. The first passivation layer 70 protects and provides electrical insulation for the LED chip 64 and can comprise many different materials, such as a dielectric material including but not limited to silicon nitride and/or any of the materials described above for the passivation layer 34 of FIG. 1A. In certain embodiments, the first passivation layer 70 is a single layer, and in other embodiments, the first passivation layer 70 comprises a plurality of layers. In certain embodiments, the first passivation layer 70 may include one or more metal-containing interlayers arranged or embedded therein that may function as a crack stop layer for any cracks that may propagate through the first passivation layer 70 as well as an additional light reflective layer. The LED chip 64 may further include a second passivation layer 72 that is arranged between the adhesion layer 68 and the reflective structure formed by the first and second reflective layers 24, 28. The second passivation layer 72 comprises a material that is more robust to etchants used to form mesa sidewalls 12′ than the material of the first reflective layer 24 and the adhesion layer 68. In certain embodiments, the second passivation layer 72 comprises a same material as the first passivation layer 70. In other embodiments, the second passivation layer 72 may embody any dielectric material that is different from and is more robust to the etchants than the first reflective layer 24. In a specific example, the first passivation layer 70 comprise SiO₂ and the second passivation layer 72 comprises SiN, SiNₓ, or Si₃N₄.

As illustrated in FIG. 4, the second passivation layer 72 is arranged between the barrier layer 32 and the second reflective layer 28. In order to provide electrical connections between the barrier layer 32 and the second reflective layer 28, a number of barrier interconnects 74 are arranged through the second passivation layer 72. In certain embodiments, the location of the barrier interconnects 74 is arranged in a laterally offset manner with respect to the reflective layer interconnects 30. In this regard, a vertical line through any portion of the barrier interconnects 74 may not intersect with the reflective layer interconnects 30. Such an arrangement may avoid etchants used on the second passivation layer 72 that provide openings for the barrier interconnects 74 from reaching the previously etched regions of the first reflective layer 24 for the reflective layer interconnects 30.

The second passivation layer 72 is also arranged between the barrier layer 32 and the first reflective layer 24 along portions of the first reflective layer 24 that are outside the second reflective layer 28. In particular, the second passivation layer 72 segregates the adhesion layer 68 and the first reflective layer 24 from the barrier layer 32 at the mesa sidewalls 12′. In this regard, the first reflective layer 24 and adhesion layer 68 may not laterally extend to the mesa sidewalls 12′. Rather, portions of the more robust second passivation layer 72 extend along portions of the n-type layer 16 and past the mesa sidewalls 12′ to bound the mesa sidewalls 12′ in a direction toward the carrier submount 66. In this manner, the second passivation layer 72 effectively seals both the first reflective layer 24 and the barrier layer 32 outside the mesa sidewalls 12′. In certain embodiments, the second passivation layer 72 forms a hermetic seal for portions of the LED chip 64 that are outside the mesa sidewalls 12′. During fabrication, the second passivation layer 72 is formed before the mesa sidewalls 12′. Accordingly, the etchants that form the mesa sidewalls 12′ may stop at the second passivation layer 72 with reduced damage to the first reflective layer 24, the adhesion layer 68, and/or the barrier layer 32. As further illustrated in FIG. 4, the p-contact 36 may be arranged to extend through the second passivation layer 72 to electrically connect with the barrier layer 32. Additionally, top passivation layers 76-1 and 76-2 may provide further protection where the top passivation layer 76-2 may cover the mesa sidewalls 12′ and portions of the second passivation layer 72 that are adjacent the p-contact 36.

As illustrated in FIG. 4, the contact plug 44 is formed on a portion of the n-type layer 16 in an opening of the p-type layer 14, the active layer 18, and a portion of the n-type layer 16. The first n-contact interconnect segment 46 may be formed through the second passivation layer 72 to electrically couple with the contact plug 44 and n-type layer 16. The first n-contact interconnect segment 46 may be formed concurrently with the second reflective layer 28 as described above. The second n-contact interconnect segment 48 is formed through an opening of the first passivation layer 70 for electrical coupling with the first n-contact interconnect segment 46. As illustrated, an extension 48′ of the second n-contact interconnect segment 48 may laterally extend on the second passivation layer 72 in a position that is between the first and second passivation layers 70, 72 for increased reflectivity. The second n-contact interconnect segment 48 is electrically coupled to an n-contact metal layer 80 that is between the carrier submount 66 and the first passivation layer 70. A third n-contact interconnect segment 82 may extend through a portion of the first passivation layer 70 for electrical coupling. The third n-contact interconnect segment 82 may include a same material as the n-contact metal layer 80, such as one or more of Al, Ti, and alloys thereof. Accordingly, the contact plug 44, the first n-contact interconnect segment 46, the second n-contact interconnect segment 48, and the third n-contact interconnect segment 82 may collectively form an n-contact interconnect of the LED chip 64.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer that is between the n-type layer and the p-type layer; and
an n-contact interconnect arranged to extend through the p-type layer and the active layer to contact a portion of the n-type layer, the n-contact interconnect comprising a contact plug and a first n-contact interconnect segment, the contact plug being arranged between the first n-contact interconnect segment and the n-type layer.

2. The LED chip of claim 1, wherein the contact plug forms a plurality of discontinuous regions on the n-type layer, and the first n-contact interconnect segment contacts the n-type layer between adjacent regions of the plurality of discontinuous regions.

3. The LED chip of claim 1, wherein the contact plug comprises chromium, aluminum-doped zinc oxide, or indium tin oxide.

4. The LED chip of claim 1, wherein the contact plug has a thickness in a range from 10 angstroms to less than 40 angstroms.

5. The LED chip of claim 1, further comprising:
a dielectric reflector layer on the p-type layer;
a metal reflector layer on the dielectric reflector layer; and
a plurality of reflective layer interconnects that extend from the metal reflector layer and through the dielectric reflector layer to form an electrically conductive path to the p-type layer.

6. The LED chip of claim 5, wherein the metal reflector layer and the first n-contact interconnect segment comprise a same material.

7. The LED chip of claim 6, wherein the same material comprises silver.

8. The LED chip of claim 5, wherein the first n-contact interconnect segment forms an extension that laterally extends on the dielectric reflector layer.

9. The LED chip of claim 8, further comprising a passivation layer on the metal reflector layer, wherein the extension is between the dielectric reflector layer and the passivation layer.

10. The LED chip of claim 9, further comprising a second n-contact interconnect segment that extends through the passivation layer and is electrically coupled to the first n-contact interconnect segment.

11. The LED chip of claim 10, wherein a width of the second n-contact interconnect segment is less than a width of the extension of the first n-contact interconnect segment.

12. The LED chip of claim 10, wherein a width of the second n-contact interconnect segment is greater than a width of the extension of the first n-contact interconnect segment.

13. The LED chip of claim 12, further comprising a first barrier layer on the extension of the first n-contact interconnect segment and a second barrier layer between the second n-contact interconnect segment and the first barrier layer, wherein a width of the second barrier layer is greater than a width of the first barrier layer.

14. The LED chip of claim 1, further comprising a p-contact electrically coupled to the p-type layer and an n-contact electrically coupled to the n-contact interconnect, wherein the p-contact and the n-contact are arranged on a same side of the active LED structure.

15. The LED chip of claim 1, further comprising:
a carrier submount on which the active LED structure is provided; and
a contact electrically coupled to the active LED structure, wherein the contact is positioned laterally adjacent the active LED structure.

16. A light-emitting diode (LED) chip, comprising:
an active LED structure comprising an n-type layer, a p-type layer, and an active layer that is between the n-type layer and the p-type layer;
a dielectric reflector layer on the active LED structure; and
a first n-contact interconnect segment that extends through the dielectric reflector layer, the p-type layer, and the active layer to contact a portion of the n-type layer, the first n-contact interconnect segment forming an extension that laterally extends on a surface of the dielectric reflector layer.

17. The LED chip of claim 16, further comprising a passivation layer on the dielectric reflector layer, wherein the extension of the first n-contact interconnect segment is between the passivation layer and the dielectric reflector layer.

18. The LED chip of claim 17, further comprising a second n-contact interconnect segment that extends through the passivation layer and is electrically coupled to the first n-contact interconnect segment.

19. The LED chip of claim 18, wherein a width of the second n-contact interconnect segment is less than a width of the extension of the first n-contact interconnect segment.

20. The LED chip of claim 19, further comprising a first barrier layer on the extension of the first n-contact interconnect segment and a second barrier layer between the second n-contact interconnect segment and the first barrier layer, wherein a width of the second barrier layer is greater than a width of the first barrier layer.

21. The LED chip of claim 16, further comprising a contact plug between the first n-contact interconnect segment and the n-type layer.

22. The LED chip of claim 21, wherein the contact plug forms a plurality of discontinuous regions on the n-type layer, and the first n-contact interconnect segment contacts the n-type layer between adjacent regions of the plurality of discontinuous regions.

23. A method, comprising:
providing an active light-emitting diode (LED) structure comprising an active layer between an n-type layer and a p-type layer, and a first opening that extends through the p-type layer, the active layer, and a portion of the n-type layer;
depositing a dielectric layer on the p-type layer and within the first opening;
forming a second opening within the first opening, the second opening extending through the dielectric layer to the n-type layer; and
depositing a first n-contact interconnect segment within the second opening, the first n-contact interconnect segment forming a lateral extension along a surface of the dielectric layer adjacent to the second opening.

24. The method of claim 23, further comprising depositing a contact plug on the n-type layer within the second opening before depositing the first n-contact interconnect segment.

25. The method of claim 23, further comprising depositing a metal layer such that a first portion of the metal layer forms a reflective layer on the dielectric layer and a second portion of the metal layer forms the first n-contact interconnect segment.

26. The method of claim 25, further comprising depositing a first portion of a barrier layer on the reflective layer and a second portion of the barrier layer on the first n-contact interconnect segment.

27. The method of claim 25, wherein an extension of the first n-contact interconnect segment laterally extends on a surface of the dielectric layer adjacent to the second opening.

28. The method of claim 27, further comprising depositing a passivation layer on the extension of the first n-contact interconnect segment.
